(19) United States
(12) Patent Application Publication
(10) Pub. No.: US 2025/0067680 A1
(43) Pub. Date: Feb. 27, 2025

(54) ILLUMINATION LIGHT SOURCE AND SUBSTRATE INSPECTION APPARATUS INCLUDING THE SAME

(71) Applicants: ELECTRONICS AND TELECOMMUNICATIONS RESEARCH INSTITUTE, Daejeon (KR); BlueTileLab, Inc, Daejeon (KR)

(72) Inventors: Dong Hoon SONG, Daejeon (KR); Hyung Woo KIM, Incheon (KR); Hong-Seok SEO, Daejeon (KR)

(21) Appl. No.: 18/751,438

(22) Filed: Jun. 24, 2024

(30) Foreign Application Priority Data
Aug. 21, 2023 (KR) 10-2023-0109361
Dec. 29, 2023 (KR) 10-2023-0196624

(51) Int. Cl. G01N 21/88; G01N 21/84; G01N 21/95

(52) U.S. Cl. CPC G01N 21/8806; G01N 21/8422; G01N 21/9501; G01N 2021/8835; G01N 2021/8845; G01N 2201/0612; G01N 2201/0635; G01N 2201/0636; G01N 2201/0638

(57) ABSTRACT

Provided are an illumination light source and a substrate inspection apparatus including the same. The substrate inspection apparatus includes a first pump light source which generates first pump light, a first gain medium which uses the first pump light to obtain a gain of first illumination light, first prisms provided at one side of the first gain medium to split the first illumination light, first mirrors provided at one side of the first prisms to reflect the first illumination light onto the first gain medium, and a first bandwidth selector provided between the first mirrors and the first prisms to select a first wavelength bandwidth of the first illumination light.

### CROSS-REFERENCE TO RELATED APPLICATIONS

This U.S. non-provisional patent application claims priority under 35 U.S.C. § 119 of Korean Patent Application Nos. 10-2023-0109361, filed on Aug. 21, 2023, and 10-2023-0196624, filed on Dec. 29, 2023, the entire contents of which are hereby incorporated by reference.

### BACKGROUND

### 1. Field of the Invention

The present disclosure herein relates to a substrate inspection apparatus, and more particularly, to an illumination light source for use in a process of inspecting a semiconductor element, and a substrate inspection apparatus including the illumination light source. The present disclosure was derived from the research conducted as part of the 2023 Startup Leap Package and Startup Commercialization Support Project (Announcement number: 2023-130) sponsored by the Korean Ministry of SMEs and Startups (Project Number: 20169373; and Project Title: Femtosecond Laser System).

### 2. Description of Related Art

Recently, near-infrared nanosecond laser light is utilized as illumination of an industrial semiconductor inspection apparatus, and thus is widely utilized in a range of applications for inspection according to thicknesses of a substrate and a thin film on the substrate. In addition, the nanosecond laser light is being usefully employed as irradiation light for measurement of a particle or a damage of the thin film.

### SUMMARY

The present disclosure provides an illumination light source capable of measuring thin films having various thicknesses or defects having various sizes, and a substrate inspection apparatus including the illumination light source.

An embodiment of the inventive concept provides an illumination light source. The illumination light source includes a first pump light source which generates first pump light, a first gain medium configured to obtain a gain of first illumination light using the first pump light, first prisms which are provided at one side of the first gain medium and split the first illumination light, first mirrors which are provided at one side of the first prisms and reflect the first illumination light onto the first gain medium, and a first bandwidth selector provided between the first mirrors and the first prisms to select a first wavelength bandwidth of the first illumination light.

In an embodiment, the illumination light source may further include a first non-linear crystal plate provided at the other side of the first gain medium, and a first filter disposed adjacent to the first non-linear crystal plate.

In an embodiment, the illumination light source may further include a first illumination aperture provided between the first non-linear crystal plate and the first gain medium.

In an embodiment, the illumination light source may include a first beam splitter disposed adjacent to the first filter.

In an embodiment, the illumination light source may include a second pump light source which generates second pump light, a second gain medium configured to obtain a gain of second illumination light using the second pump light, second prisms which are provided at one side of the second gain medium and split the second illumination light, second mirrors which are provided at one side of the second prisms and reflect the second illumination light split by the second prisms, and a second bandwidth selector provided between the second mirrors and the second prisms to select a second wavelength bandwidth of the second illumination light.

In an embodiment, the illumination light source may further include a second non-linear crystal plate provided at the other side of the second gain medium, and a second illumination filter disposed adjacent to the second non-linear crystal plate.

In an embodiment, the second non-linear crystal plate may be thinner than the first non-linear crystal plate.

In an embodiment, the illumination light source may further include a second illumination aperture provided between the second non-linear crystal plate and the second gain medium.

In an embodiment, the illumination light source may further include a grating provided between the second gain medium and the second mirrors, a quarter-wave plate provided between the second mirrors and the second gain medium, and a birefringent material plate between the quarter-wave plate and the second mirrors.

In an embodiment, the illumination light source may further include a second beam splitter disposed adjacent to the second non-linear crystal plate, and crossing the first beam splitter.

In an embodiment of the inventive concept, a substrate inspection apparatus includes a stage which accommodates a substrate, a sensor provided above the stage, an objective lens provided between the sensor and the stage, and a first illumination light source provided at one side of the objective lens to provide first illumination light onto the substrate. Here, the first illumination light source may include a first pump light source which generates first pump light, a first gain medium configured to obtain a gain of the first illumination light using the first pump light, first prisms which are provided at one side of the first gain medium and split the first illumination light, first mirrors which are provided at one side of the first prisms and reflect the first illumination light onto the first gain medium, and a first bandwidth selector provided between the first mirrors and the first prisms to select a first wavelength bandwidth of the first illumination light.

In an embodiment, the first illumination light source may further include a first non-linear crystal plate provided adjacent to the first gain medium.

In an embodiment, the substrate inspection apparatus may further include a second illumination light source provided at the other side of the objective lens to provide second illumination light onto the substrate.

In an embodiment, the second illumination light source may include a second pump light source which generates second pump light, a second gain medium configured to obtain a gain of the second illumination light using the second pump light, second prisms which are provided at one side of the second gain medium and split the second illumination light, second mirrors which are provided at one side of the second prisms and reflect the second illumination light split by the second prisms, and a second bandwidth selector provided between the second mirrors and the second prisms to select a second wavelength bandwidth of the second illumination light.

In an embodiment, the second illumination light source may further include a second non-linear crystal plate which is provided adjacent to the second gain medium and is thinner than the first non-linear crystal plate.

In an embodiment of the inventive concept, a substrate inspection apparatus includes a stage which accommodates a substrate, a sensor provided above the stage, an objective lens provided between the sensor and the stage to project the substrate, an imaging system provided between the objective lens and the sensor, a first illumination light source provided at one side of the objective lens and including a first non-linear crystal plate, and a second illumination light source provided at the other side of the objective lens and including a second non-linear crystal plate thinner than the first non-linear crystal plate.

In an embodiment, the first illumination light source may further include a first pump light source which generates first pump light, a first gain medium which absorbs the first pump light to obtain a gain of first illumination light, first mirrors which reflect the first illumination light onto the first gain medium, and first prisms provided between the first mirrors and the first gain medium.

In an embodiment, the second illumination light source may further include a second pump light source which generates second pump light, a second gain medium which absorbs the second pump light to obtain a gain of second illumination light, second mirrors which reflect the second illumination light onto the second gain medium, and are provided more than the number of the first mirrors, and second prisms provided between the second mirrors and the second gain medium.

In an embodiment, the second illumination light source may further include a grating provided between the second gain medium and the second mirrors.

In an embodiment, the second illumination light source may further include a quarter-wave plate provided between the second mirrors and the second gain medium, and a birefringent material plate between the quarter-wave plate and the second mirrors.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a diagram illustrating an example of a substrate inspection apparatus according to an embodiment of the inventive concept;

FIG. 2 is a diagram illustrating an example of a first bandwidth selector in FIG. 1;

FIG. 3 is a graph illustrating a wavelength band of first illumination light in FIG. 1;

FIG. 4 is a diagram illustrating an example of a substrate inspection apparatus according to an embodiment of the inventive concept;

FIG. 5 is a graph illustrating a wavelength band of second illumination light in

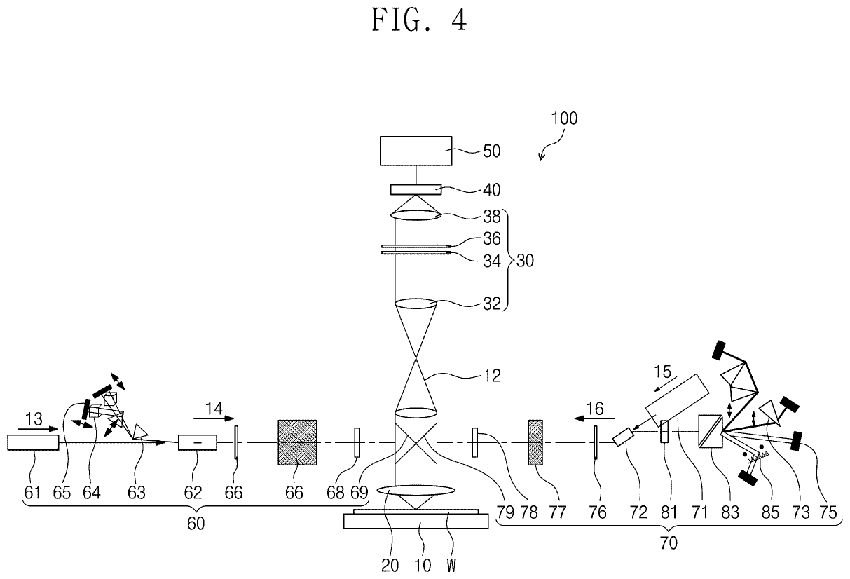

FIG. 4; and

FIG. 6 is a graph illustrating a relationship between a bandwidth and a defect size of a wavelength of a second illumination light source in FIG. 4.

### DETAILED DESCRIPTION

Hereinafter, embodiments of the inventive concept will be described in detail with reference to the accompanying drawings. Advantages and features of the present invention, and implementation methods thereof will be clarified through following embodiments described in detail with reference to the accompanying drawings. The inventive concept may, however, be embodied in different forms and should not be construed as being limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be further understood that the terms “comprises” and/or “comprising”, when used in this specification, specify the presence of stated components, operations, and/or elements, but do not preclude the presence or addition of one or more other components, operations, and/or elements. Since preferred embodiments are provided below, the order of the reference numerals given in the description is not limited thereto.

Additionally, the embodiments herein will be described with reference to cross-sectional views and/or plan views as ideal exemplary views of the present invention. In the drawings, the thicknesses of layers and regions are exaggerated for effective description of the technical contents. Accordingly, shapes of the exemplary views may be modified according to manufacturing techniques and/or allowable errors. Therefore, the embodiments of the inventive concept are not limited to the specific shape illustrated in the views, but may include other shapes created according to manufacturing processes.

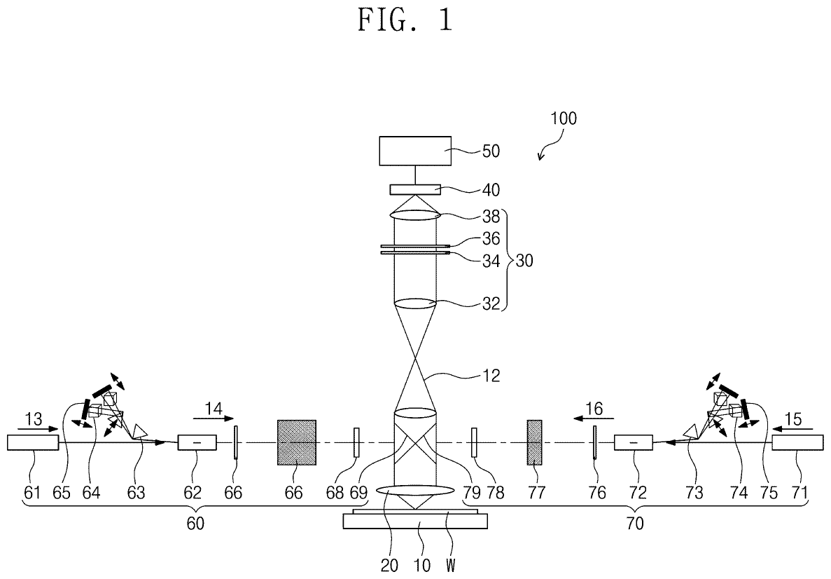

FIG. 1 illustrates an example of a substrate inspection apparatus 100 according to an embodiment of the inventive concept.

Referring to FIG. 1, the substrate inspection apparatus 100 according to an embodiment of the inventive concept may include a stage 10, an objective lens 20, an imaging system 30, an image sensor 40, a controller 50, a first illumination light source 60, and a second illumination light source 70.

The stage 10 may accommodate a substrate W. The controller 50 may control the stage 10 to move the substrate W. The stage 10 may be moved in a direction parallel to the substrate W during processes of inspecting and measuring the substrate W.

The objective lens 20 may be disposed above the stage 10. The objective lens 20 may magnify and project the substrate W onto the image sensor 40. For example, the objective lens 20 may have a numerical aperture (NA) of about 1 or less.

The imaging system 30 may be disposed between the objective lens 20 and the image sensor 40. The imaging system 30 may use reflected light 12 to project an image of the substrate W onto the image sensor 40. According to an embodiment, the imaging system 30 may include imaging relay lenses 32, an imaging polarizer 34, an imaging aperture 36, and an Oculus lens 38. The imaging relay lenses 32 may allow for adjustment of a distance between the objective lens 20 and the Oculus lens 38. The imaging polarizer 34 may be disposed between the imaging relay lenses 32 and the image sensor 40. The imaging polarizer 34 may polarize the reflected light 12. The imaging aperture 36 may be disposed between the imaging polarizer 34 and the image sensor 40. The imaging aperture 36 may define a beam size of the reflected light 12. Although not illustrated, the imaging aperture 36 may have a circular shape, and an embodiment of the inventive concept is not limited thereto. The Oculus lens 38 may be disposed between the imaging aperture 36 and the image sensor 40. The Oculus lens 38 may image the reflected light 12 on the image sensor 40. The Oculus lens 38 may include a tube lens. A magnification of the image of the substrate W may be calculated by multiplying a magnification of the objective lens 20 by a magnification of the Oculus lens 38.

The image sensor 40 may be disposed above the objective lens 20. The image sensor 40 may receive the reflected light 12 reflected from the substrate W. The image sensor 40 may use the reflected light 12 to obtain an image signal of the substrate W. The image sensor 40 may include a charge coupled device (CCD) or a CMOS image sensor.

The controller 50 may be connected to the image sensor 40. The controller 50 may use an image detection signal of the image sensor 50 to obtain the image of the substrate W.

The first illumination light source 60 may be disposed at one side of the objective lens 20. When second illumination light 16 is removed, the first illumination light source 60 may provide first illumination light 14 onto the substrate W. The first illumination light 14 may be reflected on the substrate W to generate the reflected light 12. The first illumination light 14 may generate a narrow-band image of the substrate W. According to an embodiment, the first illumination light source 60 may include a first pump light source 61, a first gain medium 62, first prisms 63, a first bandwidth selector 64, first mirrors 65, a first illumination aperture 66, a first non-linear crystal plate 67, a first illumination filter 68, and a first beam splitter 69.

The first pump light source 61 may generate first pump light 13. The first pump light 13 may be a laser diode or DPSS (diode-pumped solid-state) laser having a wavelength of about 450 nm to about 550 nm that is in a wavelength region of visible light. The first pump light 13 may be absorbed into the first gain medium 62 to generate the first illumination light 14.

The first gain medium 62 may be provided between the first pump light source 61 and the objective lens 20. The first gain medium 62 may absorb the first pump light 13 to obtain a gain of the first illumination light 14. The first gain medium 62 may include a titanium sapphire crystal.

The first prisms 63 may be provided between the first gain medium 62 and the first mirrors 65. The first prisms 63 may change a path of the first illumination light 14. The first prisms 63 may split the first illumination light 14 according to its wavelength.

The first bandwidth selector 64 may be provided between the first prisms 63 and the first mirrors 65. The first bandwidth selector 64 may select a bandwidth of a wavelength of the first illumination light 14.

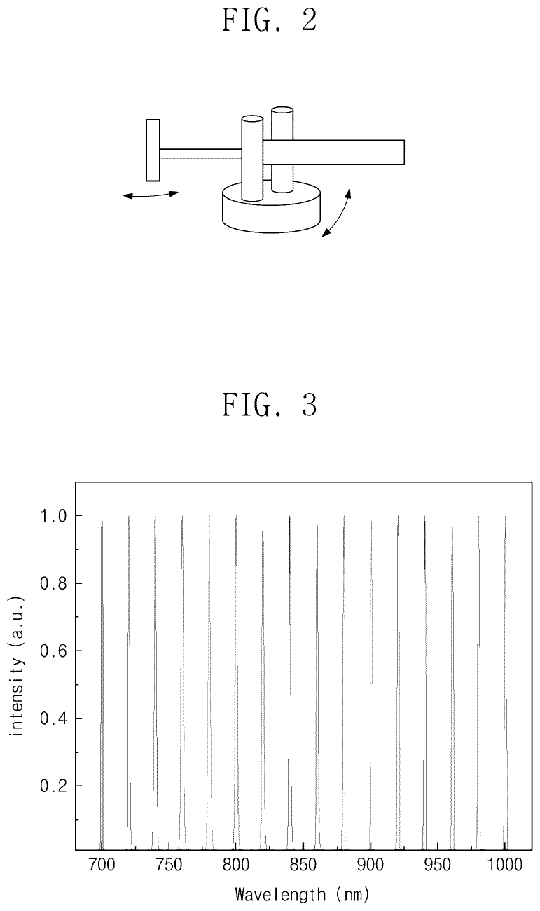

FIG. 2 illustrates an example of the first bandwidth selector 64 in FIG. 1.

Referring to FIG. 2, the first bandwidth selector 64 may include a rotating plate 22 and refraction rods 24 on the rotating plate 22. The rotating plate 22 may support and rotate the refraction rods 24. The refraction rods 24 may be provided on an edge of the rotating plate 22. The refraction rods 24 may transmit the first illumination light 14, and select a wavelength bandwidth of the first illumination light 14. Hereinafter, the bandwidth indicates a wavelength bandwidth.

Thus, the substrate inspection apparatus 100 according to an embodiment of the inventive concept may detect thin films having various thicknesses and defects having various sizes by using the first bandwidth selector 64 that selects the bandwidth of the first illumination light 14.

Referring to FIGS. 1 and 2, the first mirrors 65 may be provided at one side of the first bandwidth selector 64. The first mirrors 65 may reflect the first illumination light 14 onto the first gain medium 62. The first illumination light 14 may undergo resonance between the first mirrors 65 and the first illumination aperture 66. The number of the first mirrors 65 may be about two.

The first illumination aperture 66 may be provided at the other side of the first gain medium 62. The first illumination aperture 66 may determine a beam size of the first illumination light 14.

The first non-linear crystal plate 67 may be provided between the first illumination aperture 66 and the objective lens 20. The first non-linear crystal plate 67 may additionally increase the bandwidth of the first illumination light 14. For example, the first non-linear crystal plate 67 may include beta barium borate (BBO), periodically poled potassium titanyl phosphate (PPKTP), and periodically poled lithium niobate (PPLN). The first non-linear crystal plate 67 may further include silicon (Si), silicon nitride (SiN), aluminum gallium arsenide (AlGaAs), or silicon carbide (SIC).

The first illumination filter 68 may be provided between the first non-linear crystal plate 67 and the objective lens 20. The first illumination filter 68 may remove noise generated by the first non-linear crystal plate 67.

The first beam splitter 69 may be provided between the first illumination filter 68 and the objective lens 20. The first beam splitter 69 may reflect the first illumination light 14 onto the objective lens 20, and transmit the reflected light 12.

FIG. 3 illustrates a wavelength band of the first illumination light 14 in FIG. 1.

Referring to FIG. 3, the first illumination light 14 may have a plurality of wavelength bands.

Referring to FIG. 3, the first illumination light 14 may have a wavelength tunable range of about 700 nm to about 1000 nm.

Referring to FIG. 1 again, the second illumination light source 70 may be provided at the other side of the objective lens 20. The second illumination light source 70 may provide the substrate W with the second illumination light 16. The second illumination light 16 may generate a broad-band image of the substrate W. According to an embodiment, the second illumination light source 70 may include a second pump light source 71, a second gain medium 72, second prisms 73, a second bandwidth selector 74, second mirrors 75, a second illumination aperture 76, a second non-linear crystal plate 77, a second illumination filter 78, and a second beam splitter 79.

The second pump light source 71 may generate second pump light 15. The second pump light 15 may be absorbed into the second gain medium 72 to generate the second illumination light 16.

The second gain medium 72 may be provided between the second pump light source 71 and the objective lens 20. The second gain medium 72 may absorb the second pump light 15 to obtain a gain of the second illumination light 16. The second gain medium 72 may be the same as the first gain medium 62. The second gain medium 72 may include a titanium sapphire crystal.

The second prisms 73 may be provided between the second gain medium 72 and the second mirrors 75. The second prisms 73 may change a path of the second illumination light 16. The second prisms 73 may split the second illumination light 16 according to its wavelength.

The second bandwidth selector 74 may be provided between the second prisms 73 and the second mirrors 75. The second bandwidth selector 74 may select a bandwidth of the second illumination light 16. The second bandwidth selector 74 may be similar to the first bandwidth selector 64. Although not illustrated, the second bandwidth selector 74 may include a rotating plate and refraction rods on the rotating plate. The refraction rods of the second bandwidth selector 74 may each have a thickness different from a thickness of each of the refraction rods 24 of the first bandwidth selector 64. The thickness of the refractive rod of the second bandwidth selector 74 may be greater than the thickness of the refractive rod 24 of the first bandwidth selector 64.

Thus, the substrate inspection apparatus 100 according to an embodiment of the inventive concept may detect thin films having various thicknesses and defects having various sizes by using the first bandwidth selector 64 and the second bandwidth selector 74 that select the bandwidths of the first illumination light 14 and the second illumination light 16, respectively.

The second mirrors 75 may be provided at one side of the second bandwidth selector 74. The second mirrors 75 may reflect the second illumination light 16 onto the second gain medium 72. The second illumination light 16 may undergo resonance between the second mirrors 75 and the second illumination aperture 76. The number of the second mirrors 75 may be about two.

The second illumination aperture 76 may be provided at the other side of the second gain medium 72. The second illumination aperture 76 may determine a beam size of the second illumination light 16.

The second non-linear crystal plate 77 may be provided between the second illumination aperture 76 and the objective lens 20. The second non-linear crystal plate 77 may additionally increase the bandwidth of the second illumination light 16. The second illumination light 16 may have a bandwidth wider or greater than the bandwidth of the first illumination light 14. The second non-linear crystal plate 77 may be different from the first non-linear crystal plate 67. According to an embodiment, the second non-linear crystal plate 77 may be thinner or denser than the first non-linear crystal plate 67. The second non-linear crystal plate 77 may increase the bandwidth of the second illumination light 16 to be greater than the bandwidth of the first illumination light 14. For example, the second non-linear crystal plate 77 may include beta barium borate (BBO), periodically poled potassium titanyl phosphate (PPKTP), and periodically poled lithium niobate (PPLN). The second non-linear crystal plate 77 may further include silicon (Si), silicon nitride (SiN), aluminum gallium arsenide (AlGaAs), or silicon carbide (SiC). Alternatively, the second non-linear crystal plate 77 may be thicker or sparser than the first non-linear crystal plate 67, and an embodiment of the inventive concept is not limited thereto.

The second illumination filter 78 may be provided between the second non-linear crystal plate 77 and the objective lens 20. The second illumination filter 78 may remove noise generated by the second non-linear crystal plate 77.

The second beam splitter 79 may be provided between the second illumination filter 78 and the objective lens 20. The second beam splitter 79 may cross the first beam splitter 69 on a vertical view. The second beam splitter 79 may reflect the second illumination light 16 onto the objective lens 20, and transmit the reflected light 12.

FIG. 4 illustrates an example of a substrate inspection apparatus 100 according to an embodiment of the inventive concept.

Referring to FIG. 4, a second illumination light source 70 of the substrate inspection apparatus 100 according to an embodiment of the inventive concept may be different from a first illumination light source 60. A second illumination aperture 76, a second non-linear crystal plate 77, a second illumination filter 78, and a second beam splitter 79 of the second illumination light source 70 may be provided the same as those described with reference to FIG. 1. In addition, a stage 10, an objective lens 20, an imaging system 30, an image sensor 40, and a controller 50 may be provided the same as those described with reference to FIG. 1.

The second illumination light source 70 may include second mirrors 75 provided more than the number of first mirrors 65. The second illumination light source 70 may have more peak wavelengths than peak wavelengths of first illumination light 14. In a case in which the first mirrors 65 are about two, the second mirrors 75 may be about four.

The second illumination light source 70 may further include a quarter-wave plate 81, a birefringent material plate 83, and a grating 85.

The quarter-wave plate 81 may be provided between a second gain medium 82 and the second mirrors 75. The quarter-wave plate 81 may retard a phase of the second illumination light 16 to polarize the second illumination light 16. The second illumination light 16 may be polarized in an oval shape.

The birefringent material plate 83 may be provided between the quarter-wave plate 81 and the second mirrors 75. The birefringent material plate 83 may doubly refract the second illumination light 16 to split the second illumination light 16 into a plurality of refracted light rays.

The grating 85 may be provided between the birefringent material plate 83 and the second mirrors 75. The grating 85 may diffract the second illumination light 16 to increase a bandwidth.

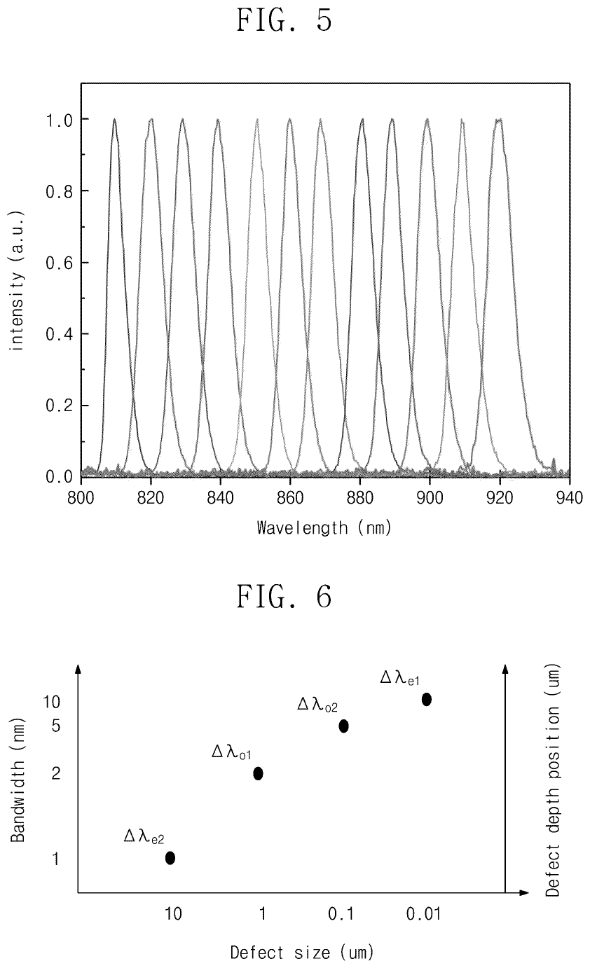

FIG. 5 illustrates a wavelength band of the second illumination light 16 in FIG. 4.

Referring to FIG. 5, the second illumination light 16 may have a plurality of wavelength bands. The second illumination light 16 may have a wavelength tunable range of about 700 nm to about 1000 nm.

FIG. 6 illustrates a relationship between a bandwidth and a defect size of a wavelength of the second illumination light source 70 in FIG. 4.

Referring to FIG. 6, when the defect size is decreased, the bandwidth of the wavelength of the second illumination light 16 may be increased. That is, the bandwidth of the wavelength of the second illumination light 16 may be in inverse proportion to the defect size.

Thus, the substrate inspection apparatus 100 according to an embodiment of the inventive concept may detect thin films having various thicknesses and particles having various sizes by using the second illumination light 16 having the broader wavelength bandwidth than the first illumination light 14.

The illumination light source according to the embodiment of the inventive concept may detect the thin films having various thicknesses and the defects having various sizes by using the bandwidth selector that selects the wavelength bandwidth of the first illumination light.

As above, the embodiments have been described herein with reference to the accompanying drawings. The specific terms used herein are to describe embodiments of the inventive concept but are not intended to limit the scope of the inventive concept. Thus, it is understood that the present invention should not be limited to these embodiments but various changes and modifications can be made by one ordinary skilled in the art within the spirit and scope of the present invention as hereinafter claimed. Therefore, the technical scope of the inventive concept is not limited to the contents described in the detailed description of the specification, but should be determined by the claims.

What is claimed is:

1. An illumination light source comprising:
a first pump light source configured to generate first pump light;
a first gain medium configured to obtain a gain of first illumination light using the first pump light;
first prisms provided at one side of the first gain medium and configured to split the first illumination light;
first mirrors provided at one side of the first prisms and configured to reflect the first illumination light onto the first gain medium; and
a first bandwidth selector provided between the first mirrors and the first prisms to select a first wavelength bandwidth of the first illumination light.

2. The illumination light source of claim 1, further comprising:
a first non-linear crystal plate provided at the other side of the first gain medium; and
a first filter disposed adjacent to the first non-linear crystal plate.

3. The illumination light source of claim 2, further comprising a first illumination aperture provided between the first non-linear crystal plate and the first gain medium.

4. The illumination light source of claim 2, further comprising a first beam splitter disposed adjacent to the first filter.

5. The illumination light source of claim 4, further comprising:
a second pump light source configured to generate second pump light;
a second gain medium configured to obtain a gain of second illumination light using the second pump light;
second prisms provided at one side of the second gain medium and configured to split the second illumination light;
second mirrors provided at one side of the second prisms and configured to reflect the second illumination light split by the second prisms; and
a second bandwidth selector provided between the second mirrors and the second prisms to select a second wavelength bandwidth of the second illumination light.

6. The illumination light source of claim 5, further comprising:
a second non-linear crystal plate provided at the other side of the second gain medium; and
a second illumination filter disposed adjacent to the second non-linear crystal plate.

7. The illumination light source of claim 6, wherein the second non-linear crystal plate is thinner than the first non-linear crystal plate.

8. The illumination light source of claim 6, further comprising a second illumination aperture provided between the second non-linear crystal plate and the second gain medium.

9. The illumination light source of claim 6, further comprising:
a grating provided between the second gain medium and the second mirrors;
a quarter-wave plate provided between the second mirrors and the second gain medium; and
a birefringent material plate between the quarter-wave plate and the second mirrors.

10. The illumination light source of claim 6, further comprising a second beam splitter disposed adjacent to the second non-linear crystal plate, and crossing the first beam splitter.

11. A substrate inspection apparatus comprising:
a stage configured to accommodate a substrate;
a sensor provided above the stage;
an objective lens provided between the sensor and the stage; and
a first illumination light source provided at one side of the objective lens to provide first illumination light onto the substrate,
wherein the first illumination light source comprises:
a first pump light source configured to generate first pump light;
a first gain medium configured to obtain a gain of the first illumination light using the first pump light;
first prisms provided at one side of the first gain medium and configured to split the first illumination light;
first mirrors provided at one side of the first prisms and configured to reflect the first illumination light onto the first gain medium; and
a first bandwidth selector provided between the first mirrors and the first prisms to select a first wavelength bandwidth of the first illumination light.

12. The substrate inspection apparatus of claim 11, wherein the first illumination light source further comprises a first non-linear crystal plate provided adjacent to the first gain medium.

13. The substrate inspection apparatus of claim 12, further comprising a second illumination light source provided at the other side of the objective lens to provide second illumination light onto the substrate.

14. The substrate inspection apparatus of claim 13, wherein the second illumination light source comprises:
a second pump light source configured to generate second pump light;
a second gain medium configured to obtain a gain of the second illumination light using the second pump light;
second prisms provided at one side of the second gain medium and configured to split the second illumination light;
second mirrors provided at one side of the second prisms and configured to reflect the second illumination light split by the second prisms; and
a second bandwidth selector provided between the second mirrors and the second prisms to select a second wavelength bandwidth of the second illumination light.

15. The substrate inspection apparatus of claim 14, wherein the second illumination light source further comprises a second non-linear crystal plate which is provided adjacent to the second gain medium and is thinner than the first non-linear crystal plate.

16. A substrate inspection apparatus comprising:
a stage configured to accommodate a substrate;
a sensor provided above the stage;
an objective lens provided between the sensor and the stage to project the substrate;
an imaging system provided between the objective lens and the sensor;
a first illumination light source provided at one side of the objective lens and comprising a first non-linear crystal plate; and
a second illumination light source provided at the other side of the objective lens and comprising a second non-linear crystal plate thinner than the first non-linear crystal plate.

17. The substrate inspection apparatus of claim 16, wherein the first illumination light source further comprises:
a first pump light source configured to generate first pump light;
a first gain medium configured to absorb the first pump light to obtain a gain of first illumination light;
first mirrors configured to reflect the first illumination light onto the first gain medium; and
first prisms provided between the first mirrors and the first gain medium.

18. The substrate inspection apparatus of claim 17, wherein the second illumination light source further comprises:
a second pump light source configured to generate second pump light;
a second gain medium configured to absorb the second pump light to obtain a gain of second illumination light;
second mirrors configured to reflect the second illumination light onto the second gain medium, and provided more than the number of the first mirrors; and
second prisms provided between the second mirrors and the second gain medium.

19. The substrate inspection apparatus of claim 18, wherein the second illumination light source further comprises a grating provided between the second gain medium and the second mirrors.

20. The substrate inspection apparatus of claim 18, wherein the second illumination light source comprises:
a quarter-wave plate provided between the second mirrors and the second gain medium; and
a birefringent material plate between the quarter-wave plate and the second mirrors.
